(19) United States
(12) Patent Application Publication
(10) Pub. No.: US 2004/0140436 A1
(43) Pub. Date: Jul. 22, 2004

(54) Transfer method and apparatus, exposure method and apparatus, method of manufacturing exposure apparatus, and device manufacturing method

(76) Inventor: Hidekazu Kikuchi, Watari-gun (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/754,718

(22) Filed: Jan. 12, 2004

Related U.S. Application Data
(63) Continuation of application No. 09/557,156, filed on Apr. 25, 2000, now abandoned.

(30) Foreign Application Priority Data
Apr. 26, 1999 (JP) 11-117460

(51) Int. Cl. H01J 37/20

(52) U.S. Cl. 250/442.11; 250/492.23

(57) ABSTRACT

An elevator unit (26) including three support members (48c) capable of vertically moving and rotating are arranged above a transportation position where an object (45) is transferred by a transfer arm (70). When the object (45) is transferred to the transportation position, the support members (48c) move downward to a position P3 and rotate in a predetermined angle α°. The support members slightly move upward to receive the object (45) from the arm (70). When the arm withdraws, the support members (48c) move downward to a stage (RST) to place the object (45) on the stage. The support members (48c) then rotate, in the predetermined angle α°, in a direction opposite to the direction in which they rotated before, and then move upward to a position P2. This makes it possible to mount the object on a mount surface smoothly, without any problem, even if the mounted surface is located lower in level than the upper surface of the stage.

### BACKGROUND OF THE INVENTION

1. Field of the Invention

The present invention relates to a transfer method and apparatus, an exposure method and apparatus, a method of manufacturing an exposure apparatus, and a device manufacturing method. More particularly, the present invention relates to a transfer method and apparatus suitable for the transfer of a mask as an object to be transferred, an exposure method and apparatus using the transfer method and apparatus for the transfer of a mask, a method of manufacturing the exposure apparatus, and a device manufacturing method using the exposure apparatus.

2. Description of the Related Art

Various exposure apparatuses have been used for lithographic processes in the manufacture of semiconductor devices, liquid crystal display devices. Recently, optical exposure apparatuses such as reduction projection exposure apparatuses based on the step-and-repeat method (so-called steppers) and scanning exposure apparatuses based on the step-and-scan method (so-called scanning steppers) are frequently used.

With the stepper, a mask or reticle (to be generically referred to as reticle hereinafter) is held on a reticle stage by vacuum chucking or the like. This stage is capable of fine movement (including θ rotation (rotation around the Z-axis)) in the X-Y plane. The scanning stepper comprises a reticle coarse adjustment stage and a reticle fine adjustment stage. The reticle coarse adjustment stage moves in the scanning direction (e.g., the Y-axis direction) with predetermined strokes, and on the reticle coarse adjustment stage the reticle fine adjustment stage holding the reticle by vacuum chucking, makes fine movements on the XY plane (including θ rotation (around the Z axis)).

In any conventional optical exposure apparatus, a reticle is mounted on the upper surface of the stage capable of θ rotation. For this reason, such an apparatus uses the following reticle transfer sequence. First, a transfer robot arm holding a rectangular reticle moves horizontally to a position above the stage capable of θ rotation. The transfer robot arm then moves downward to load the reticle on the stage, and slightly moves downward. Thereafter, the arm returns to the initial position.

With a conventional optical exposure apparatus, a driving mechanism such as a total of four push/pull rods, two each set perpendicular to both sides of the stage holding a reticle, or two sets of voice coil motors having the same functions are used.

As semiconductor devices increase the degree of integration every year, circuit patterns become very fine, thus causing the device rule (practical minimum line width) to be 0.1 μm or less in time. In order to achieve exposure for such fine patterns, many problems must be solved in optical exposure apparatuses. Under the circumstances, there is almost no doubt that an electron beam exposure apparatus (to be referred to as an “EB exposure apparatus” hereinafter) will become one of the promising choices for the next generation.

With an EB exposure apparatus, it must be kept in a vacuumed chamber, so that the reticle cannot be chucked by vacuum as above, and requires a different approach such as an electrostatic method.

Furthermore, since the above driving mechanism for the θ rotation of a reticle is indispensable for the conventional exposure apparatus, the arrangement of the reticle stage driving mechanism is complicated.

### SUMMARY OF THE INVENTION

The present invention has been made in consideration of the above situation, and has as its first object to provide a new transfer method of transferring an object to be transferred onto a stage, and more specifically, a transfer method which can mount the object on an object mount surface of the stage, even if the mount surface is lower in level than the upper surface of the stage.

It is the second object of the present invention to provide an exposure method which can improve exposure precision.

It is the third object of the present invention to provide a new transfer apparatus for transferring an object to be transferred onto a stage, and more specifically, a transfer apparatus which can mount the object on an object mount surface of the stage even if the mount surface is lower in level than the upper surface of the stage.

It is the fourth object of the present invention to provide an exposure apparatus which can improve exposure precision.

It is the fifth object of the present invention to provide a device manufacturing method that can manufacture high-integration microdevices with high productivity.

In the first aspect of this invention, there is provided a transfer method of transporting an object to be transferred to/from a stage, comprising the steps of: supporting one surface of said object on a plurality of support members; loading said object supported by said plurality of support member onto said stage; and withdrawing said plurality of support members from said object to an other surface side of said object after loading said object onto the stage.

According to the transfer method of the present invention, the one surface of the object is supported by the plurality of prepared support members. Then the object supported by the plurality of support members is loaded onto the stage. After the object is loaded onto the stage, the plurality of support members are withdrawn to the other surface side of the object. That is, according to the transfer method of the present invention, the object can be loaded onto the stage by the support members, moving in only a direction almost perpendicular to the object mount surface of the stage.

In this case, said supporting step comprises the substeps of: moving relatively said object and said plurality of support members such that contact portions of said plurality of support members are located on said other surface side of said object, the contact portions coming into contact with said object; and moving said plurality of support members in respective predetermined directions within a moving plane perpendicular to a direction in which said object and said support member relatively are moved. In such a case, even if, for example, the plurality of support members are at first, located on the opposite side of the object to the stage, one surface of the object can be supported by the plurality of support members by moving relatively the object and the plurality of support members such that contact portions of the plurality of support members are located on the one surface side of the object which come into contact with the object, on the one surface side (stage side) of the object, and then moving the plurality of support members in respective predetermined directions within a plane perpendicular to the direction in which the object and the support members relatively are moved.

In this case, said supporting step further comprises the substep of supporting said object on the contact portions of said support members by relatively moving said object and said plurality of support members after the substep of respectively moving said plurality of support members in the respective predetermined directions. In such a case, even if the object and the plurality of support members coming into contact with the object are spaced apart from each other after the plurality of support members move in the respective predetermined directions, one surface of the object can be supported by the plurality of support members after the substep of relatively moving the object and the plurality of support members.

According to the transfer method of the present invention, said loading step comprises the substeps of: relatively moving said plurality of support members and said stage so as to contact said one surface of said object with said stage; and moving said plurality of support members thereafter in respective predetermined directions within a plane perpendicular to a direction in which said support members and said stage relatively are moved. In this case, after the object is loaded onto the stage, the plurality of support members can be separated from the object by relatively moving the plurality of support members supporting one surface (the surface on the stage side) of the object and the stage so as to contact the one surface of the object with the stage, and then moving the plurality of support members in respective predetermined directions within the plane perpendicular to the direction in which the support members and the stage relatively are moved. That is, the object is loaded onto the stage by relatively moving the plurality of support members in the direction perpendicular to the mount surface on the stage, and moving the support members within the plane perpendicular to the direction of the relative movements. Even if, therefore, the object mount surface is lower in level than the upper surface of the stage, the object can be mounted on the mount surface without any problem.

The method of the present invention can further comprise the steps of: moving relatively said stage and said plurality of support members such that contact portions of said support members are located on said one surface side of said object supported on said stage, said contact portions coming into contact with said object; moving said plurality of support members in respective predetermined directions within a plane perpendicular to a direction in which said stage and said plurality of support members relatively are moved; and unloading said object from said stage by relatively moving said plurality of support members and said stage.

In this case, the object and the plurality of support members relatively move such that the contact portions of the support members are located on one surface side of the object supported on the stage, the contact portion coming into contact with the object, and the plurality of support members move in respective predetermined directions within the plane perpendicular to the direction in which the stage and the support members relatively are moved. Thereafter, the object is unloaded from the stage by relatively moving the plurality of support members and the stage. Therefore, the object can be unloaded from the stage by using the plurality of support members which are withdrawn to the other surface side of the object on the stage after the above mentioned loading step.

According to the transfer method of the present invention, as is obvious, the contact portions of the plurality of support members which come into contact with the object, may be moved from one surface side to the other surface side or in the opposite direction outside the object. Alternatively, openings through which the plurality of support members can pass may be formed in the object. In this case, the contact portions of the plurality of support members which come into contact with the object, can be moved from one surface side to the other surface side through the openings. In this case, the term “openings” indicates a concept that includes notches or the like formed in the outer circumferential portion of the object, as well as through-holes partly opening wide or the like formed within the object. Note that the term “openings” has this meaning herein.

In the second aspect of this invention, there is provided an exposure method comprising: supporting one surface of a first object by a plurality of support members; loading said first object supported by said plurality of support members onto a stage; withdrawing said plurality of support members from said first object to an other surface side of said object after said first object is loaded onto said stage; and transcribing a pattern of said first object onto a second object through an optical system while detecting positions of said first object supported on said stage and said second object in an optical axis direction of said optical system.

According to this method, since the first object can be loaded on the stage by using the transfer method of the present invention, even if the mount surface of the stage on which the first object is mounted is lower in level than the upper surface of the stage, the first object can be mounted on the mount surface without any problem by using the support members that move in only a direction almost perpendicular to the mount surface of the stage on which the first object is mounted. As a consequence, the first object can be located near the lower surface of the stage. Therefore, in transcribing the pattern formed on the first object onto the second object through the optical system, not only the position of the second object in the optical axis direction of the optical system but also the position of the first object in the optical axis direction which is held on the stage can be precisely detected by a focal position detection system which uses an oblique incident light method or the like. This makes it possible to perform focusing/leveling control on the first and second objects, and transcribe the pattern of the first object onto the second object, i.e., exposure, with high precision.

In this case, exposure may be performed while the first and second objects are stationary in a plane perpendicular to the optical axis. Alternatively, the pattern of said first object may be transcribed while said second object and the stage holding the first object are synchronously moved in predetermined directions within planes perpendicular to said optical axis of said optical system.

In the third aspect of this invention, there is provided a transfer apparatus for transporting an object to be transferred to/from a stage, comprising; a plurality of support members which supports one surface of said object; and a first driving mechanism which drives said plurality of support members in a first direction between a first position on one surface side of said object and a second position on an other surface side opposite to said one surface side.

In this specification, the term “first direction” does not mean a direction in a normal sense but means the axis direction corresponding to the first direction, said plurality of support members making reciprocal movement along the axis.

In this aspect, the apparatus includes the first driving mechanism which drives the plurality of support members in the first direction between the first position on one surface side of the object and the second position on the other surface side opposite to the one surface side. In loading the object onto the stage, therefore, the first driving mechanism drives the plurality of support members supporting one surface of the object to the first position to load the object onto the stage at some midpoint during the driving or near the first position. The first driving mechanism then drives the plurality of support members to the second position on the other surface side opposite to one surface side of the object on the stage and withdraw the plurality of support members from the stage so that the plurality of support members do not interfere with the object after the object is loaded. That is, the object can be loaded onto the stage by moving the support members in the first direction almost perpendicular to the object mount surface of the stage.

In this case, this apparatus may further comprise a second driving mechanism which drives the plurality of support members in respective directions within a plane perpendicular to the first direction. In this case, the plurality of support members can be driven in the plane perpendicular to the first direction by the second driving mechanism. In loading the object onto the stage, therefore, the object can be mounted on the object mount surface on the stage by a combination of driving of the plurality of support members in the first direction by the first driving mechanism and driving of the plurality of support members in the plane perpendicular to the first direction by the second driving mechanism, without any problem, even if the object mount surface of the object is located lower than the upper surface of the stage.

In this case, the second driving mechanism can rotate said plurality of support members around a predetermined axis in the first direction in moving said plurality of support members in a plane perpendicular to the first direction. In this case, the stage need not have any θ rotating mechanism. This makes it possible to simplify the arrangement of the stage.

In the transfer apparatus of the present invention, openings are preferably formed in the object, the plurality of support members being able to be inserted/withdrawn through said openings in the first direction. In this case, arcuated through-holes, or notches formed in the outer circumferential portion of said object are formed as the above openings, to allow the contact portions of the plurality of support members which come into contact with the object to pass through the object via the openings. In addition, rotational movement of the object or the support member in a predetermined angle can inhibit the plurality of support members from passing through the openings. Even if, therefore, there is almost no gap around the object mount surface of the stage, one surface of the object can be smoothly supported by the plurality of support members both when the object is loaded onto the stage and when it is unloaded from the stage.

In the fourth aspect of this invention, there is provided an exposure apparatus for transcribing a pattern formed on a first object onto a second object through an optical system, comprising: a stage which mounts said first object; and a transfer system which transfers said first object to/from said stage; wherein the transfer system includes a plurality of support members which supports one surface of said first object, and a first driving mechanism which drives said plurality of support members in a first direction between a first position on one surface side of said object and a second position on said other surface side opposite to said one surface.

According to this apparatus, the first object can be loaded onto the stage by driving the plurality of support members in the first direction using the first driving mechanism of the transfer system. Even if the first object mount surface of the stage is lower in level than the upper surface of the stage, the first object can be loaded onto the mount surface without any problem. As a consequence, the first object can be located near the lower surface of the stage. This makes it possible to use a focusing/leveling sensor such as a multiple focal position detection system which uses an oblique incident light method on the first object side as well as on the second object side. Therefore, focusing/leveling control can be performed on the first object on which a pattern is formed, and the pattern of the first object can be transcribed (projected by exposure), onto the second object with higher precision.

In this case, if the first object is a reflection type mask, the stage may be designed to move only near an exposure position where the pattern is transcribed onto the second object. Alternatively, the stage may be designed to move between the transportation position where the first object is transported to/from the transfer system and the exposure position where the pattern is transcribed onto the second object. In this case, a transmission type mask can be used as the first object.

An exposure apparatus according to the present invention can comprise an interferometer system which manages both the transport and exposure positions and a position of the stage during movement between the transport and exposure positions.

In this case, said interferometer system comprises: a first interferometer subsystem which manages the position of said stage, located at the transportation position, in a two-dimensional plane perpendicular to the first direction; and a second interferometer subsystem which manages the position of said stage, located at the exposure position, in the two-dimensional plane, and wherein interferometer beams from said first and second interferometer subsystems simultaneously irradiate a single reflecting surface of said stage while said stage is moving between the transportation position and the exposure position. In such a case, when interferometer beams from said first and second interferometer subsystems simultaneously irradiate a single reflecting surface of said stage, the interferometer system can be preset. This makes it possible to reduce the size of the stage.

In addition, in a lithographic process, a pattern can be accurately formed on a substrate by exposure using an exposure apparatus of the present invention, thereby manufacturing high-integration microdevices with high yield. According to still another aspect of the present invention, therefore, there is provided a device manufacturing method using the exposure apparatus of the present invention.

### BRIEF DESCRIPTION OF THE DRAWINGS

FIG. 1 is a schematic diagram of an exposure apparatus according to an embodiment of the present invention;

FIG. 2 is an enlarged view illustrating an elevator unit and related elements in the apparatus shown in FIG. 1;

FIG. 3 is a plan view illustrating a reticle stage base in the apparatus shown in FIG. 1;

FIG. 4 is a sectional view taken along a line IV-IV in FIG. 2;

FIG. 5 is an enlarged view illustrating a portion enclosed with a circle E in FIG. 4;

FIG. 6 is a sectional view taken along a line VI-VI in FIG. 4;

FIG. 7 is a block diagram of the control system of the apparatus in FIG. 1;

FIG. 8 is a flow chart for explaining an embodiment of a device manufacturing method according to the present invention; and

FIG. 9 is a flow chart showing processing in step 204 in FIG. 8.

### DESCRIPTION OF THE PREFERRED EMBODIMENTS

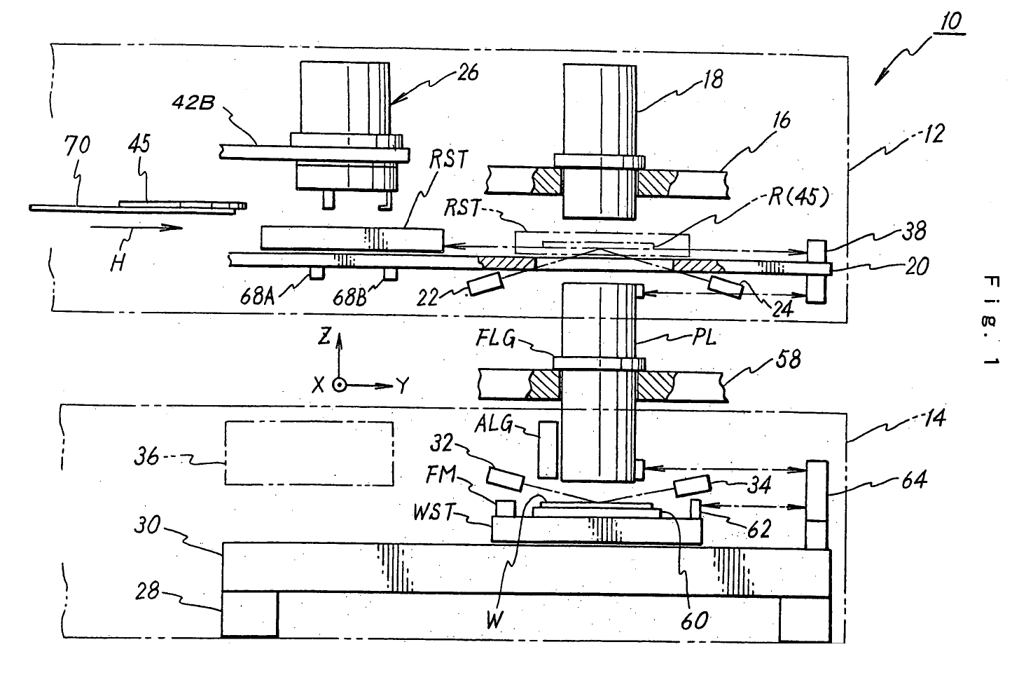

An embodiment of the present invention will be described below with reference to FIGS. 1 to 7. FIG. 1 is a schematic diagram of an exposure apparatus 10 according to the embodiment. This exposure apparatus comprises a transfer apparatus according to the present invention. The exposure apparatus 10 is an electron beam exposure apparatus (EB exposure apparatus) using an EBPS (Electron Beam Projection System) for transcribing a pattern of a reticle R as a mask onto a wafer W as a substrate by a scanning exposure method using an electron beam. Structural details may be referenced to the prior art, such as the U.S. Pat. No. 5,952,667, which are fully incorporated by reference herein.

The exposure apparatus 10 includes a reticle vacuum chamber 12 and wafer vacuum chamber 14.

The reticle vacuum chamber 12 houses a columnar illumination system 18 supported by a support frame 16 and has an axis coinciding with the Z-axis direction (vertical axis direction), a reticle stage base 20 placed along the X-Y plane (horizontal plane) below the illumination system 18, a reticle stage RST as a first stage that moves on the reticle stage base 20 two-dimensionally in the X and Y directions while holding the reticle R, a reticle AF (Auto-Focusing)/AL (Auto-Leveling) system (22, 24) detecting the Z position of the reticle R and its tilt with respect to the X-Y plane, an elevator unit 26 as a transfer apparatus, a reticle library (not shown in Figs), and the like.

The wafer vacuum chamber 14 houses a plurality of (four in this embodiment) vibration isolating units 28 (the vibration isolating units on the rear side of the drawing are not shown in FIG. 1) arranged on the floor of the wafer vacuum chamber 14, a wafer stage base 30 held almost horizontally by the vibration isolating units 28, a wafer stage WST as a second stage that moves on the wafer stage base 30 two-dimensionally in the X and Y directions, a wafer AF/AL system (32, 34) detecting the Z position of the wafer W and its tilt with respect to the X-Y plane, a wafer loader 36, and the like.

The exposure apparatus 10 also includes a projection lens PL serving as an optical system. The upper and lower end portions of the projection lens PL are partly housed in the reticle vacuum chamber 12 and wafer vacuum chamber 14, respectively.

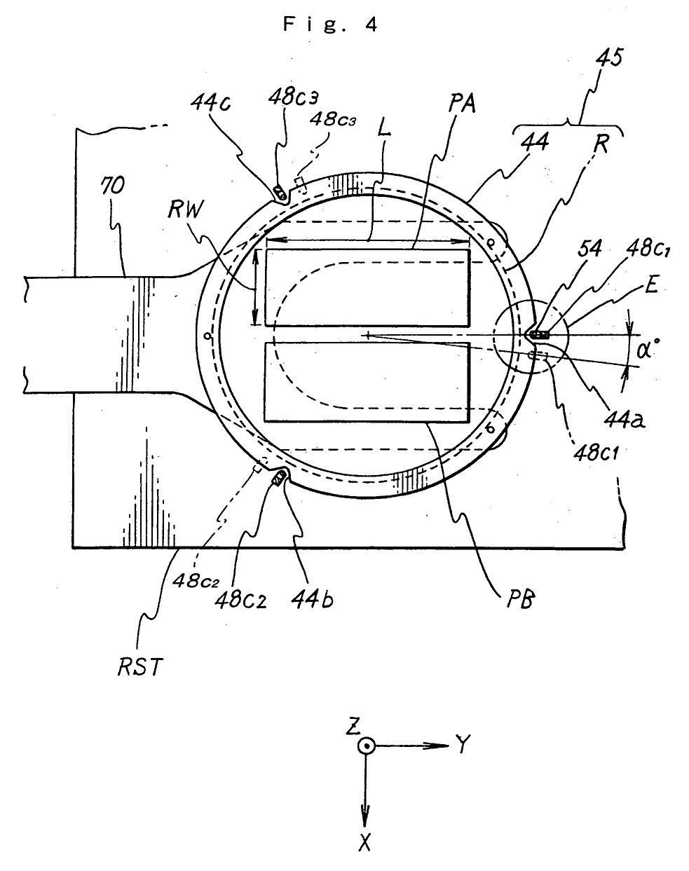

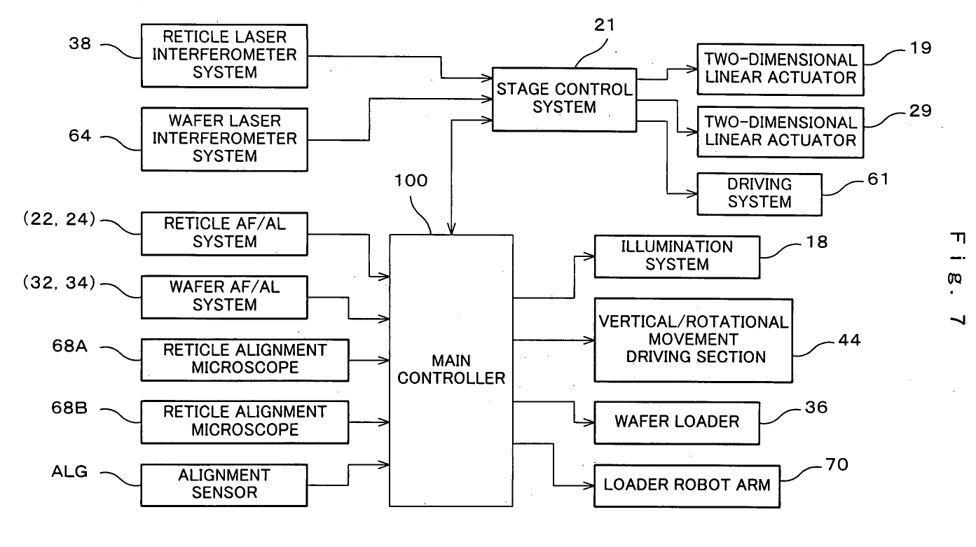

The illumination system 18 includes an electron gun which has an electron source consisting of LaB₆ (lanthanum hexaboride), a blanking electrode, an illumination lens formed of an electron lens, a rectangular aperture, a shaping lens formed of an electron lens, a deflector (none of which are shown in Figs.), and the like. The illumination system 18 shapes an electron beam emitted from the electron gun into an electron beam 1 by 1 mm square through the blanking electrode, illumination lens, rectangular aperture, and shaping lens, and irradiates an area (referred to as a sub-field) about 1 by 1 mm square on the reticle R with the electron beam having almost uniform energy density. The deflector has a sufficient deflecting power corresponding to a width RW (see FIG. 4) of one split pattern area of the reticle R (to be described later) in a non-scanning direction. This deflector is controlled by a main controller 100 (not shown in FIG. 1; see FIG. 7) (to be described later) controlling the overall apparatus. One split pattern area is one of a plurality of split pattern areas obtained by splitting a pattern to be transcribed onto one division area on the wafer. In this embodiment, two split pattern areas PA and PB, each having a length L in the scanning direction and a width RW in the non-scanning direction, are formed on the reticle R, as shown in FIG. 4.

The reticle stage RST holds the reticle R by electrostatic chucking, and is driven two-dimensionally in the X and Y directions by a two-dimensional linear actuator 19 (not shown in FIG. 1; see FIG. 7) such as a magnetic levitation type plane motor. In this embodiment, as this magnetic levitation type two-dimensional linear actuator 19, an actuator having a Z drive coil in addition to X and Y drive coils, which is disclosed in detail in, for example, Japanese Patent Laid-Open No.11-69764 and corresponding international application PCT/JP98/03688 and US application, is used. Therefore, the reticle stage RST can be finely driven in the Z-axis direction and inclined with respect to the X-Y plane as well as being moved within the X-Y plane. Details disclosed in said Japan Patent Laid-Open, international application and corresponding US application, are fully incorporated by reference herein.

Obviously, the reticle stage RST can be driven two-dimensionally by two linear motors.

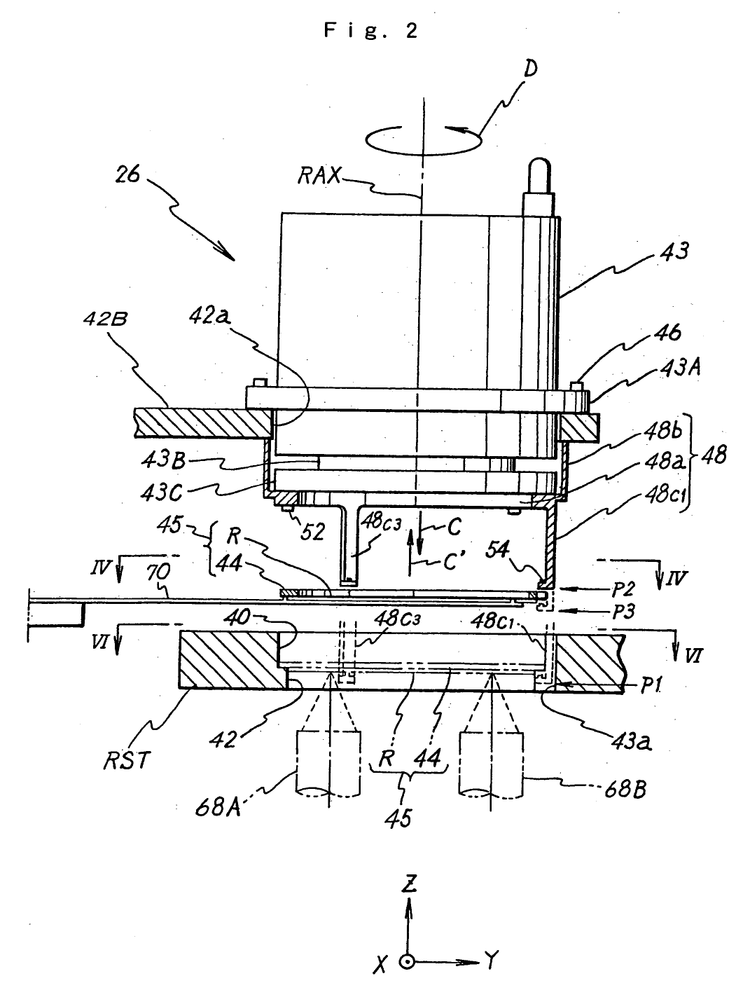

As shown in FIG. 2, the reticle stage RST has a hole 40 formed in its central portion. The hole 40 has a circular shape when viewed from the top. A circular opening 42, which is concentric with the hole 40, is formed on the bottom surface of the hole 40 leaving its peripheral portion. An electrostatic chuck (not shown in Figs.) is placed on the bottom surface of the hole 40 to chuck a support ring 44 that is a doughnut-shaped (ring-shaped) frame for supporting the reticle R. In this embodiment, since a thin reticle (so-called stencil mask) formed by processing a silicon wafer as a material to a thickness of about several μm is used as the reticle R, it is difficult to transfer the reticle R alone. The reticle R, therefore, is mounted on the support ring 44, and they are both transferred together. In this embodiment, the reticle R and support ring 44 constitute a reticle assembly 45 serving as an object to be transferred (or first object).

Referring back to FIG. 1, a reticle laser interferometer system (an interferometer) 38 fixed, on the reticle stage base 20, detects the position of the reticle stage RST in the X-Y plane with a resolution of 0.5 nm to 1 nm with reference to the projection lens PL. The measurement value obtained by the reticle laser interferometer system 38 is sent to a stage control system 21 (not shown in FIG. 1; see FIG. 7) and to the main controller 100 through the stage control system 21. The arrangement of the reticle laser interferometer system 38 will be described later.

As the above reticle AF/AL system for detecting the Z position of the reticle R and its tilt with respect to the X-Y plane, a multiple focal position detection system based on an oblique incident light method is used. This system is comprised of an irradiation optical system 22 for sending a beam, which forms a plurality of slit images onto the reticle R located on the object surface side of the projection lens PL, to the reticle R along an oblique direction with respect to the optical axis direction (Z-axis direction) of the projection lens PL, and a light-receiving optical system 24 for receiving the respective imaging beams reflected by the reticle surface through slits. As this multiple focal position detection system (22, 24), a system having an arrangement similar to that disclosed in, for example, Japanese Patent Laid-Open No. 5-190423 and corresponding U.S. Pat. No. 5,502,311 is used, which are fully incorporated by reference herein.

The detection values obtained by the multiple focal position detection system (22, 24) are sent to the main controller 100 and to the stage control system 21 through the main controller 100. The stage control system 21 drives the reticle stage RST, through the two-dimensional linear actuator 19, in the Z direction and inclines the reticle stage RST with respect to X-Y plane so as to keep a predetermined distance between the reticle R and the projection lens PL.

The elevator unit 26 is arranged just above a position (loading/unloading position) where the reticle R is to be transported to/from the reticle stage RST. As shown in detail in FIG. 2, the elevator unit 26 includes a vertical/rotational movement driving section 43 which is fixed to a support frame 42B with a plurality of bolts 46 through a flange portion 43A, and inserted downward into a circular opening 42a of the support frame 42B, and a driven member 48 mounted on a table 43C formed from a circular plate-like member which is mounted on an end portion of a vertical/rotational movement shaft 43B of the vertical/rotational driving section 43.

More specifically, a vertical/rotational movement mechanism (not shown in Figs.) incorporated in the vertical/rotational movement driving section 43 drives the vertical/rotational movement shaft 43B in the vertical direction (Z-axis direction) indicated by arrows C and C′ in FIG. 2, the direction indicated by an arrow D in FIG. 2 and the opposite direction thereto, i.e., the rotational direction (θ direction) around the Z-axis.

The driven member 48 is integrally formed by a ring-like mount portion 48a fixed to the lower surface of the table 43C with a plurality of screws 52, a cover portion 48b serving as a cylindrical cover extending upward from an outer edge portion of the mount portion 48a, and three finger portions 48c₁, 48c₂, and 48c which extend downward as support members arranged at intervals of about 120° on the lower surface of the mount portion 48a. Obviously, the mount portion 48a, cover portion 48b, and finger portions 48c₁ to 48c₃ can be formed by separate members and integrated into one unit by welding or the like. In the following description, the cover portion 48b and finger portions 48c₁ to 48c₃ shall be referred to as the “cover 48b” and “hook members 48c₁ to 48c₃”, respectively, or generically referred to as “hook member 48c”.

The upper portion of the cover 48b is open, and a predetermined gap is present between the lower portion of a side surface of the cover 48b and the outer surface of the table 43C. However, since the bottom portion of the cover 48b is integrally formed with the mount portion 48a, no gap is present between the cover 48b and the mount portion 48a. Even if, therefore, dust and the like are accidentally produced upon vertical movement or rotation of the vertical/rotational movement shaft 43B, the cover portion 48b can prevent the dust and the like from dropping onto the reticle stage RST side or can effectively suppress such action.

The above three hook portions 48c₁ to 48c₃ have the same structure. A hook support portion for supporting the support ring 44 as a member of the reticle assembly 45 is formed on the distal end (lower end) of each hook portion 48c. A rubber pin 54 made of fluorine-based rubber as an elastic member is fixed on the upper surface of the support portion of each hook portion 48c. In this embodiment, the material for the support ring 44 is a nonmetallic material such as silicone carbide, and the material for the hook portion 48c is metal such as iron or stainless steel. If, the support ring 44 and hook portion 48c come into direct contact with each other, the support ring 44 may be damaged, or dust may be produced from the contact portion. Therefore, the rubber pin 54 is fixed to the upper surface of the support portion of the hook portion 48c to prevent these members from coming into direct contact. In addition, since fluorine-based rubber is used as the material for the rubber pin 54, the friction coefficient θ between the rubber pin 54 and the support ring 44 is relatively large (e.g., μ>0.4), which makes it possible to reliably support (hold) the reticle assembly 45 in the manner described later.

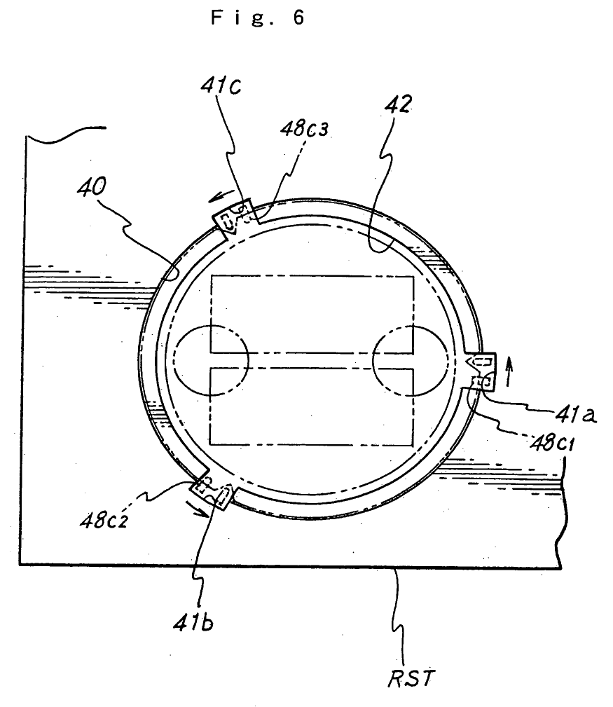

As shown in FIG. 4, which is a sectional view taken along a line IV-IV in FIG. 2, a V-shaped notch 44a and U-shaped notches 44b and 44c as openings are formed in the outer circumferential portion of the support ring 44 at intervals of about 120° in correspondence with three hook portions 48c₁, 48c₂, and 48c₃. As shown in FIG. 6, which is a sectional view taken along a line VI-VI in FIG. 2, notched portions 41a, 41b, and 41c, each having a substantially trapezoidal shape when viewed from the top are formed in the circumferential wall of the hole 40 at intervals of about 120° in correspondence with the three hook portions 48c₁, 48c₂, and 48c₃. As will be described later, these notched portions 41a, 41b, and 41c have the function of allowing the hook portions 48c₁ to 48c₃ to make θ rotation within a predetermined angle α° and inhibiting them from rotating more.

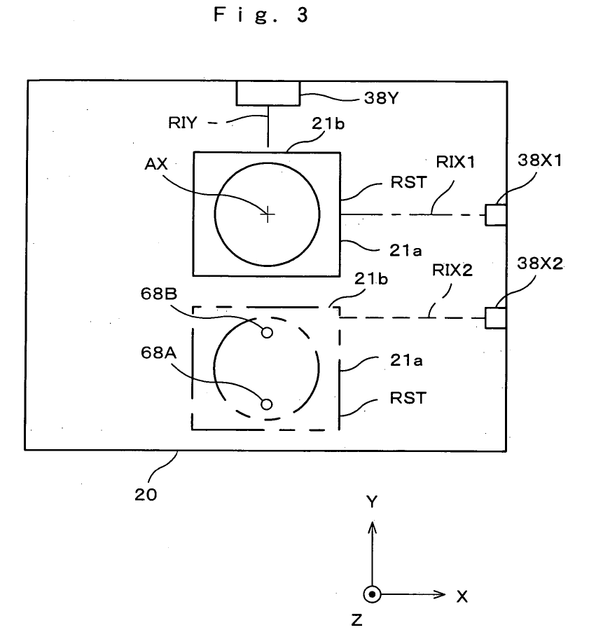

FIG. 3 is a plane view of the reticle stage base 20. Referring to FIG. 3, the reticle stage RST indicated by the solid line is in a state wherein the center of the reticle stage RST almost coincides with the center of an exposure position at which the pattern of the reticle R is transcribed onto the wafer W, i.e., the center of the projection lens PL indicated by a center AX of the cross-shaped mark. The reticle stage RST indicated by the virtual line (chain double-dashed line) is at a position at which the reticle R is transported. As is obvious from FIG. 3, in this embodiment, the reticle stage RST is designed to move between the reticle R transportation position and the exposure position. In other words, transport (loading/unloading) of the reticle R with respect to the reticle stage RST and exposure of the reticle R are performed at different positions. In spite of the fact that the transmission type reticle R is used, the reticle R (reticle assembly 45) can be transported to/from the reticle stage RST from above by the elevator unit 26, as will be described later.

Reflecting surfaces 21a and 21b are respectively formed on a side surface of the reticle stage RST in the X direction (+X side) and a side surface thereof in the Y direction (+Y side) by mirror polishing. The position of the reticle stage RST in the Y-axis direction, i.e., the scanning direction, is always measured by a reticle Y laser interferometer 38Y for irradiating the reflecting surface 21b with a measurement beam RIY. The position of the reticle stage RST in the X-axis direction, i.e., the non-scanning direction, in exposure operation is measured by a reticle X laser interferometer 38X1 for irradiating the reflecting surface 21a of the reticle stage RST at the exposure position. The X-direction position of the reticle stage RST during loading/unloading of the reticle R (reticle assembly 45) is measured by a reticle X laser interferometer 38X2 capable of irradiating the reflecting surface 21a of the reticle stage RST at the transportation position with a measurement beam RIX2. In this embodiment, the reticle Y laser interferometer 38Y and reticle X laser interferometer 38X2 constitute a first interferometer subsystem for managing the position of the reticle stage RST in a plane (X-Y plane) perpendicular to the first direction (Z-axis direction) while the stage is at the transportation position. The reticle Y laser interferometer 38Y and reticle X laser interferometer 38X1 constitute a second interferometer subsystem for managing the position of the reticle stage RST in the X-Y plane while the stage is at the exposure position.

As is also obvious from FIG. 3, the reticle X laser interferometer 38X1 and reticle X laser interferometer 38X2 must be switched during movement of the reticle stage RST. In this embodiment, however, the reflecting surface 21a of the reticle stage RST can be irradiated simultaneously with the measurement beam (interferometer beam) RIX2 from the reticle X laser interferometer 38X2 as a member of the first interferometer subsystem and the measurement beam RIX1 from the reticle X laser interferometer 38X1 as a member of the second interferometer subsystem while the reticle stage RST moves between the transportation position and the exposure position. In this embodiment, the stage control system 21 performs the above interferometer switching, in accordance with an instruction from the main controller 100, after an interferometer measurement value is preset to make a measurement value from the interferometer that has not been used coincide with a measurement value from an interferometer that has been used at the position where the reflecting surface 21a is irradiated simultaneously with measurement beams from the interferometers 38X1 and 38X2 during movement of the reticle stage RST in the Y direction. In this embodiment, an interferometer measurement value can be present, and interferometers can be switched in this manner. Even if, therefore, a reflecting surface of the reticle stage RST is not irradiated with the measurement beams (interferometer beams) RIX1 and RIX2 during movement of the reticle stage RST, no problem arises. For this reason, a movement stroke can be sufficiently ensured for the reticle stage RST, and the size of the stage can be reduced. In addition, the position controllability of the reticle stage RST is good.

In addition, to minimize any error due to rotation of the reticle stage RST during the above interferometer switching, the reticle Y laser interferometer 38Y as a multi-axis interferometer is used to measure Y-direction position and θ rotation measurement. Furthermore, measurement beams from the respective interferometers 38X1, 38X2, and 38Y are irradiated at almost the same height position as that of the pattern surface of the reticle R (see FIG. 1).

As described above, in this embodiment, the reticle laser interferometer system 38 is comprised of the reticle Y laser interferometer 38Y and the two reticle X laser interferometers 38X1 and 38X2. These three interferometers are representatively shown as the reticle laser interferometer system 38 in FIG. 1.

As shown in FIG. 3, in this embodiment, reticle alignment microscopes 68A and 68B are arranged as a pair of mark detection systems on the reticle stage base 20 at a position near the reticle R transportation position. A reticle alignment mark formed on the reticle R can be observed at the transportation position by this pair of reticle alignment microscopes 6.8A and 68B. The observation data obtained by the reticle alignment microscopes 68A and 68B is sent to the main controller 100 (see FIG. 7). The reticle alignment microscopes 68A and 68B are similar to those disclosed in, for example, Japanese Patent Laid-Open No. 61-121437 and corresponding U.S. Pat. No. 4,710,029, which are fully incorporated by reference herein.

Referring back to FIG. 1, a flange portion FLG is located slightly above the middle portion of the lens barrel portion in the height direction, and the projection lens PL is supported by a support frame 58 through the flange portion FLG. As this projection lens PL, a reduction projection lens constituted by a plurality of electron lens is used. The reduction ratio (projection magnification) β of the projection lens PL is ¼ in this case.

The wafer stage WST is driven two-dimensionally on the wafer stage base 30 in the X and Y directions by a two-dimensional linear actuator 29 (not shown in FIG. 1; see FIG. 7) constituted by a magnetic levitation type planar motor and the like disclosed in, for example, Japanese Patent Laid-Open No. 9-17848, 9-17847, 9-17846 and corresponding U.S. Pat. No. 5,925,956, which are fully incorporated by reference herein.

The wafer W is fixed on the upper surface of the wafer stage WST by a wafer holder 60 using electrostatic chucking. The wafer holder 60 can be finely driven in the Z-axis direction, an oblique direction with respect to the X-Y plane, and a rotational direction (θ direction) around the Z-axis by a driving system 61 (not shown in FIG. 1; see FIG. 7) including, for example, three voice coil motors which support the wafer holder at three points and can finely drive the wafer holder independently in the Z-axis. The position of the wafer stage WST in the X-Y plane is detected by a wafer laser interferometer system 64 using a moving mirror 62 with a resolution of 0.5 nm to 1 nm with reference to the projection lens PL. The measurement value obtained by this wafer laser interferometer system 64 is sent to the stage control system 21 and to the main controller 100 through the stage control system 21 (see FIG. 7).

A reference mark plate FM on which a reference mark for baseline measurement and other reference marks is placed on the upper surface of the wafer stage WST. The surface of this reference mark plate FM is almost flush with the surface of the wafer W.

As the wafer AF/AL system for detecting the Z position of the wafer W and its tilt, a multiple focal position detection system which uses an oblique incident light method is used. This system is comprised of an irradiation optical system 32 for sending a beam, which forms a plurality of slit images onto the wafer W located on the imaging plane side of the projection lens PL, to the wafer W along an oblique direction with respect to the optical axis direction (Z-axis direction) of the projection lens PL, and a light-receiving optical system 34 for receiving the respective imaging beams reflected by the wafer surface through slits. As this multiple focal position detection system (32, 34), a system having an arrangement similar to that disclosed in, for example, Japanese Patent Laid-Open No. 5-190423 and corresponding U.S. Pat. No. 5,502,311 is used. The detection values obtained by this multiple focal position detection system (32, 34) are sent to the main controller 100 and to the stage control system 21 through the main controller 100. The stage control system 21 drives the wafer holder 60, through the driving system 61, in the Z direction and tilts the wafer holder 60 so as to keep a predetermined distance between the wafer W and the projection lens PL (see FIG. 7).

The exposure apparatus 10 of this embodiment also has an off-axis type alignment microscope, e.g., an imaging alignment sensor ALG using an image processing method, arranged on a side surface of the projection lens PL to detect the position of an alignment mark (wafer mark) formed with each shot area (division area) on the wafer W. The measurement result obtained by the imaging alignment sensor ALG is sent to the main controller 100 (see FIG. 7). As the imaging alignment sensor ALG, a sensor having an arrangement similar to that disclosed in, for example, Japanese Patent Laid-Open No. 7-321030 and corresponding U.S. Pat. No. 5,721,605 is used, which are fully incorporated by reference herein.

Prior to exposure, the main controller 100 performs EGA (Enhanced Global Alignment) for calculating the arrangement coordinates of the shot areas on the wafer W in a stage coordinate system by statistical computation disclosed in Japanese Patent Laid-Open No. 61-44429 and corresponding U.S. Pat. No. 4,780,617 on the basis of the measured positions of the wafer marks, which are fully incorporated by reference herein.

FIG. 7 shows the above-described components in the control system of the exposure apparatus 10. The control system shown in FIG. 7 has the main controller 100 as a main component, which is a microcomputer-(or workstation).

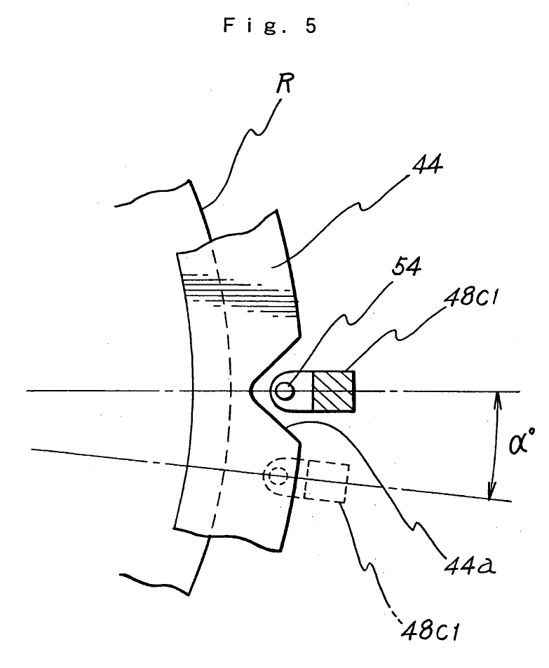

In the exposure apparatus 10 having the above arrangement, operation of transferring the reticle assembly 45, which is constituted by the reticle R and the support ring 44 mounting it, will be described next with reference to FIGS. 1, 2, 4, 5, and 6. FIG. 5 is an enlarged view of the portion enclosed with a circle E in FIG. 4.

\mathring{1} First of all, a loader robot arm 70 serving as a transfer arm supporting the support ring 44 of the reticle assembly 45 moves horizontally as indicated by an arrow H in FIG. 1 to transfer the reticle assembly 45 toward the transportation position in accordance with an instruction from the main controller 100. The loader robot arm 70 then moves to the transportation position just below the elevator unit 26 and stops at the position in accordance with an instruction from the main controller 100. FIG. 2 shows a state wherein the loader robot arm 70 is at rest at the transportation position. At this time, the three hook members 48c₁ to 48c₃ are standing by at positions where they do not interfere with the support ring 44, and more specifically, the upper movement limit position (second position) indicated by reference symbol P2 in FIG. 2. In this state, as shown in FIG. 4, which is a sectional view taken along a line IV-IV in FIG. 2, the three hook members 48c₁, 48c₂, and 48c₃ just correspond to the notches 44a, 44b, and 44c of the support ring 44.

\mathring{2} The driven member 48 is then driven downward by a predetermined amount, together with the vertical/rotational movement shaft 43B, by the vertical/rotational movement driving section 43 of the elevator unit 26 in accordance with an instruction from the main controller 100. As a consequence, the three hook members 48c₁, 48c₂, and 48c₃ move downward to a position P3 in FIG. 2 and stop at the position. In this downward movement, the three hook members 48c₁, 48c₂, and 48c₃ pass through the notches 44a, 44b, and 44c formed in the support ring 44.

\mathring{3} The vertical/rotational movement driving section 43 rotates the driven member 48, together with the vertical/rotational movement shaft 43B, in a direction opposite to the direction indicated by the arrow D in FIG. 2 in a predetermined angle α° in accordance with an instruction from the main controller 100. As a consequence, the three hook members 48c₁, 48c₂, and 48c₃ rotate together in the predetermined angle α° in a direction opposite to the direction indicated by the arrow D in FIG. 2. FIG. 4 shows the three hook members 48c₁, 48c₂, and 48c₃ after this rotation by the virtual lines. At this time, the three hook members 48c₁, 48c₂, and 48c₃ are located below the support ring 44 (see FIGS. 4 and 5).

\mathring{4} The driven member 48 is driven upward, together with the vertical/rotational movement shaft 43B, by a predetermined amount by the vertical/rotational movement driving section 43 in accordance with an instruction from the main controller 100. As a consequence, the three hook members 48c₁, 48c₂, and 48c₃ move upward, and the rubber pins 54 fixed on the upper surfaces of the hooked support portions come into contact with the bottom surface of the support ring 44. The three hook members 48c₁, 48c₂, and 48c₃ further move upward to raise the reticle assembly 45. As a consequence, the reticle assembly 45 separates from the loader robot arm 70. In this manner, the reticle assembly 45 is transported from the loader robot arm 70 to the three hook members 48c₁, 48c₂, and 48c₃.

\mathring{5} The loader robot arm 70 moves in a direction opposite to the direction indicated by the arrow H and returns to the initial position in accordance with an instruction from the main controller 100.

\mathring{6} When the loader robot arm 70 withdraws to a position where it does not interfere with the reticle assembly 45, the vertical/rotational movement driving section 43 moves the driven member 48 downward by a predetermined amount, together with the vertical/rotational movement shaft 43B, in accordance with an instruction from the main controller 100, so as to load the reticle assembly 45 on the reticle stage RST. More specifically, the reticle assembly 45 (i.e., the support ring 44) supported on the three hook members 48c₁, 48c₂, and 48c₃ is driven downward to a position just above the position where they come into contact with the bottom surface of the hole 40, and is stopped there.

\mathring{7} Upon confirming that the hook members 48c₁, 48c₂, and 48c₃ have stopped, the alignment marks (positioning mark) formed on the reticle R are observed by using the pair of reticle alignment microscopes 68A and 68B mounted on the reticle stage base 20, and the main controller 100 calculates any positional offset of the alignment mark from the reference point, i.e., error components of the reticle R in the X, Y, and θ directions, on the basis of the observation result. The main controller 100 gives the vertical/rotational movement driving section 43 of the elevator unit 26 a command value for correcting an error component Δθ in the θ direction. In accordance with this command value, the vertical/rotational driving section 4.3 rotates the driven member 48, i.e., the hook members 48c₁, 48c₂, and 48c₃, to correct the θ-direction error of the reticle R immediately before it is loaded on the reticle stage RST. Meanwhile, command values for correcting error components ΔX and ΔY of the reticle R in the X and Y directions are sent from the main controller 100 to the stage control system 21. The stage control system 21 then finely drives the reticle stage RST two-dimensionally in the X and Y directions, thus correcting the X and Y errors of the reticle R immediately before it is loaded on the reticle stage RST.

\mathring{8} When the errors of the reticle R in the X, Y, and θ directions are corrected, i.e., the reticle R is aligned, in the above manner, the vertical/rotational movement driving section 43 drives the driven member 48 slightly downward, together with the vertical/rotational movement shaft 43B, in accordance with an instruction from the main controller 100. With this operation, the three hook members 48c₁, 48c₂, and 48c₃ move downward to a position P1 (first position) in FIG. 2 and stop there. During this downward movement, the reticle assembly 45 supported on the three hook members 48c₁, 48c₂, and 48c₃ comes into contact with the bottom surface of the hole 40 of the reticle stage RST. When the three hook members 48c₁, 48c₂, and 48c₃ further move downward, the reticle assembly 45 is transported onto the reticle stage RST.

\mathring{9} The vertical/rotational movement driving section 43 rotates the driven member 48, together with the vertical/rotational movement shaft 43B, in the direction indicated by the arrow D in FIG. 2 in the predetermined angle α° in accordance with an instruction from the main controller 100. As a consequence, the three hook members 48c₁, 48c₂, and 48c₃ rotate together in the predetermined angle α° in the direction indicated by the arrow D in FIG. 2 (see FIG. 6), and just correspond to the inner portions of the notches 44a, 44b, and 44c of the support ring 44. Thereafter, the vertical/rotational movement driving section 43 raises the vertical/rotational movement shaft 43B and driven member 48 together in accordance with an instruction from the main controller 100. With this operation, the three hook members 48c₁, 48c₂, and 48c₃ pass through the notches 44a, 44b, and 44c of the support ring 44 of the reticle assembly 45 mounted on the reticle stage RST, and return (withdraw) to a position P2 in FIG. 2.

With the above operation, loading of the vertical/rotational movement driving section 43 onto the reticle stage RST is completed.

The reticle assembly 45 can be unloaded from the reticle stage RST by a reverse procedure to that indicated by \mathring{1} to \mathring{9} without performing operation \mathring{7}.

As is obvious from the above description, in this embodiment, the first and second driving mechanisms are constituted by the elevator unit 26 and vertical/rotational movement driving section 43, and a measurement unit is constituted by the reticle alignment microscopes 68A and 68B and main controller 100.

Other operations in the exposure process which are to be performed after loading of the reticle assembly 45 in the exposure apparatus 10, will be briefly described next.

First of all, the wafer loader 36 loads the wafer W onto the wafer stage WST under the control of the main controller 100, and preparatory processing, e.g., baseline measurement, is performed by using the reference mark plate FM on the wafer stage WST and the alignment sensor ALG in accordance with a predetermined procedure. Preparatory processing such as baseline measurement is disclosed in detail in, for example, Japanese Patent Laid-Open No. 4-324923 and corresponding U.S. Pat. No. 5,243,195, which are fully incorporated by reference herein.

The main controller 100 then executes alignment measurement such as EGA disclosed in, for example, Japanese Patent Laid-Open No. 61-44429 and corresponding U.S. Pat. No. 4,780,617 by using the imaging alignment sensor ALG. In this operation, if the wafer W needs to be moved, the main controller 100 controls at least a current value to be supplied to a predetermined armature coil of the two-dimensional linear actuator 29 or a current direction through the stage control system 21, thereby moving the wafer stage WST holding the wafer W in a desired direction. After the alignment measurement, exposure operation based on the scanning exposure scheme is performed as follows.

In this exposure operation, the wafer stage WST is first moved such that the X and Y positions of the wafer W coincide with the scanning start position at which the first split area in the first division area (first shot) on the wafer W. At the same time, the reticle stage RST is moved such that the X and Y positions of the reticle R coincide with the scanning start position for the split pattern area PA. In accordance with an instruction from the main controller 100, the stage control system 21 synchronously moves the reticle R and wafer W, through the two-dimensional linear actuators 19 and 29, in opposite directions along the Y-axis direction at a speed ratio corresponding to the projection magnification of the projection lens PL on the basis of the X and Y position information of the reticle R and the X and Y position information of the wafer W which are respectively measured by the reticle laser interferometer system 38 and wafer laser interferometer system 64. At the same time, an electron beam 1 by 1 mm square which is transmitted from the illumination system 18 onto the reticle R at a speed much higher than these scanning speeds is deflected in a non-scanning direction (X direction) to scan all the first split pattern area PA in the non-scanning direction. This deflection is performed by a deflector in the illumination system 18 in accordance with an instruction from the main controller 100. With this operation, the entire first split pattern area PA is transcribed to the first split area in the first shot on the wafer-W. During this scanning exposure on the first split area, the stage control system 21 performs focusing/leveling control by finely driving the reticle stage RST in the Z direction and tilting with respect to the X-Y plane on the basis of the measurement values obtained by the reticle AF/AL system (22, 24), and also performs focusing/leveling control by finely driving the wafer holder 60 in the Z direction and inclining with respect to the X-Y plane on the basis of the measurement values obtained by the wafer AF/AL system (32, 34).

After transcribing of the first split pattern area PA is completed in this manner, the stage control system 21 continuously moves the reticle stage RST and wafer stage WST synchronously along U-shaped paths. When the X and Y positions of the wafer W coincide with a scanning start position for exposure in the second split area in the first shot on the wafer W, and the X and Y positions of the reticle R coincide with a scanning start position for the split pattern area PB, the pattern of the split pattern area PB is transcribed to the second split area adjacent to the first split area in the first shot on the wafer W in the manner as described above. With this process, transcribing of the reticle pattern onto the first shot on the wafer W is completed.

As soon as transcribing the reticle pattern onto one shot area is completed in this manner, the wafer stage WST is stepped to a scanning starting position for exposure of the next shot, and a reticle pattern is transcribed onto the next shot area in the same manner as described above. In this manner, stepping and transcribing of a reticle pattern are sequentially repeated to transcribe patterns corresponding to the required number of shots onto the wafer W.

As described above, according to this embodiment, the reticle assembly 45 (reticle R) can be loaded/unloaded on/from the reticle stage RST from above by using the elevator unit 26. Therefore, the reticle assembly 45 as an object to be transferred can be loaded/unloaded to/from the reticle stage RST as a stage, without any problem in spite of the fact that the reticle mount surface is lower in level than the upper surface of the reticle stage RST. For this reason, in this embodiment, as described above, the multiple focal position detection system (22, 24) using the oblique incident light method can be installed on the object surface side of the projection lens PL without any problem. This makes it possible to perform focusing/leveling control on the reticle R as well as focusing/leveling control on the wafer W during scanning exposure. The exposure apparatus 10 of this embodiment can therefore transcribe a reticle pattern onto a wafer with higher precision than a conventional exposure apparatus having only a wafer-side AF/AL system.

In addition, since the elevator unit 26 has the three hook members 48c₁ to 48c₃ capable of θ rotation as well as vertical movement, the reticle assembly 45 can be caused to make θ rotation before the reticle assembly 45 is loaded onto the reticle stage RST. This makes it unnecessary for the reticle stage RST to have a θ stage (θ rotation mechanism) like a conventional stage, thus simplifying the structure of the reticle stage RST.

And in the exposure apparatus 10, since the pair of reticle alignment microscopes 68A and 68B are arranged below the transportation position for the reticle assembly 45, reticle alignment can be performed immediately before the reticle assembly 45 is loaded on the reticle stage RST by observing/measuring the reticle alignment mark with the reticle alignment microscopes 68A and 68B, correcting any θ error of the reticle with the elevator unit 26, and correcting X and Y errors of the reticle by moving the reticle stage RST in the X and Y directions.

The above arrangement of the elevator unit 26 is an example, and the arrangement of the transfer apparatus according to the present invention is not limited to this. More specifically, according to the above embodiment, the first and second driving mechanisms are formed from the vertical/rotational movement driving section 43. However, the first and second driving mechanisms may be formed from different mechanisms. In this case, a mechanism having only a vertical movement shaft may be used as the first driving mechanism, and a mechanism for separately driving a plurality of (at least three) support members fixed on the distal end of the vertical movement shaft in a horizontal plane, e.g., the radial direction of the reticle assembly 45 may be used as the second driving mechanism. In this case, the lower surface of the reticle assembly 45 as an object to be transferred, can be supported by the support members without forming notches as openings in the reticle assembly 45.

In the above embodiment, notches are formed as openings in the outer circumferential portion of the support ring 44 of the reticle assembly 45 as an object to be transferred. However, the present invention is not limited to this. The support ring 44 may have arcuated openings which partly open wide to allow the hook members 48c₁ to 48c₃ to pass through. In this case, the hook support portions (portions that contact an object to be transferred) of the hook members 48c₁ to 48c₃ can pass through the openings, and the reticle assembly 45 can be supported by the support members by inhibiting the support portions from passing through the openings upon rotation within a predetermined angle. Even if, therefore, there is almost no gap around the reticle assembly mount portion of the reticle stage RST, the reticle assembly 45 can be smoothly loaded/unloaded on/from the reticle stage RST.

The above embodiment includes the three hook members 48c as support members. The number of hook members is set to three in order to stably support a disk-like object to be transferred (first object) with a simplest arrangement. However, the present invention is not limited to this. Two, four or more support members may be used. When two support members are to be used, the portion of each support member coming into contact with the object to be transferred may be shaped in certain areas along the outer edge of the object to steadily support the object.

In the above embodiment, when the reticle assembly 45 is to be loaded onto the reticle stage RST, the three hook members 48c serving as support members are driven vertically. If, however, the stage can move vertically, the stage may be moved vertically, or the support members and stage may be relatively driven vertically.

According to the above embodiment, the present invention is applied to the electron beam exposure apparatus using the EBPS method. However, the application range of the present invention is not limited to this. For example, the present invention can be suitably applied to a DUV (Deep Ultraviolet) exposure apparatus having an ultra-high pressure mercury lamp or KrF excimer laser device (oscillation wavelength: 248 nm) as a light source, a VUV (Vacuum Ultraviolet) exposure apparatus having an Arf excimer laser device (oscillation wavelength: 193 nm) or F₂ laser device (oscillation wavelength: 157 nm) as a light source, or an EUV (Extreme Ultraviolet) exposure apparatus having a light source for emitting extreme ultraviolet light in the soft X-ray region.

Such an exposure apparatus may be a scanning exposure apparatus (e.g., U.S. Pat. No. 5,473,410) designed to transcribe a pattern of a mask by synchronously moving the mask and a substrate, or a step-and-repeat exposure apparatus designed to transcribe a pattern of a mask onto a substrate while the mask and substrate are at rest and sequentially step the substrate.

A projection lens (projection optical system) as a member of such an exposure apparatus may be of a reduction magnification type, one-to-one magnification type, or enlargement magnification type. As the projection lens (projection optical system), a lens made of a glass material that transmits far-ultraviolet light, e.g., quartz or fluorite is used when far-ultraviolet light such as an excimer laser beam is to be used. When an F₂ laser beam or EUV light is to be used, a catadioptric or reflection optical system is used, and a reflecting reticle may be used. When a reflecting reticle is to be used, the reticle may be loaded/unloaded near the exposure position.

In the case a linear motor (see U.S. Pat. No. 5,623,853 or U.S. Pat. No. 5,528,118) is to be used for a wafer stage or reticle stage, the motor may be of an air levitation type using an air bearing or magnetic levitation type using Lorentz force or reactance force. The stage may be of a type that moves along a guide or a guide-less type having no guide.

The reaction force generated upon movement of the wafer stage may be mechanically relieved to the floor (ground) by using a frame member as disclosed in, for example, Japanese Patent Laid-Open No. 8-166475 and corresponding U.S. Pat. No. 5,528,118, which are fully incorporated by reference herein.

The reaction force generated upon movement of the reticle stage may also be mechanically relieved to the floor (ground) by using a frame member as disclosed in, for example, Japanese Patent Laid-Open No. 8-330224 and corresponding U.S. patent application Ser. No. 08/416,558, which are fully incorporated by reference herein.

Application of this exposure apparatus is not limited to an exposure apparatus for the manufacture of semiconductor devices. For example, this apparatus can be widely applied to an exposure apparatus for liquid crystal devices, which forms patterns of liquid crystal display element on a rectangular glass plate by exposing it, an exposure apparatus used for the manufacture of thin magnetic heads, and the like.

An exposure apparatus of the present invention such as the above embodiment can be manufactured by incorporating an illumination system constituted by a plurality of electron lenses and the like and a projection lens in an exposure apparatus body, and adjusting them, and by mounting a reticle stage, wafer stage, and elevator unit each constituted by many mechanical parts, peripheral parts, and the like on the exposure apparatus body, connecting wires and pipes, and performing overall adjustment (electric adjustment, operation checks, and the like). Such an exposure apparatus is preferably manufactured in a clean room where temperature, degree of cleanliness, and the like are managed.

A semiconductor device is manufactured through the following steps: the step of designing the function and performance of the device; the step of manufacturing a reticle on the basis of the design step; the step of manufacturing a wafer from a silicon material; the step of transcribing a reticle pattern on the wafer by using the exposure apparatus of the above embodiment; the step of assembling the device (including dicing, bonding, and packaging process), the inspection step, and the like.

<<Device Manufacturing Method>>

A device manufacturing method using the above exposure apparatus and method in a lithographic process will be described in detail next.

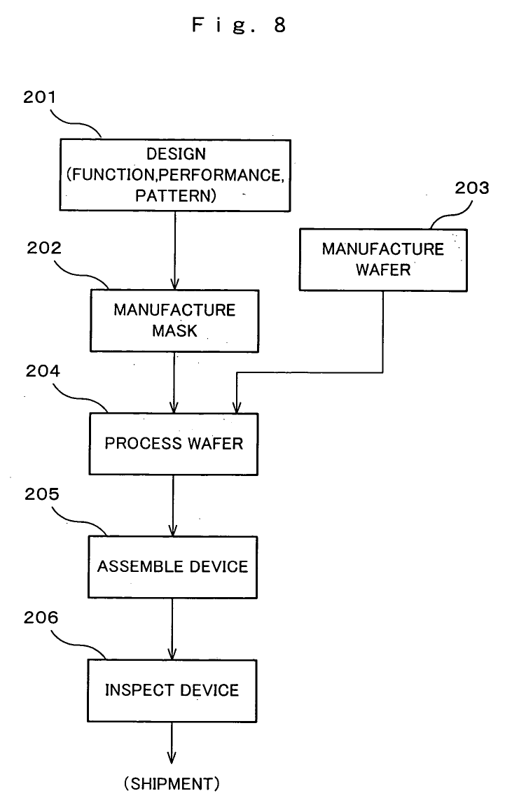

FIG. 8 is a flow chart showing an example of manufacturing a device (a semiconductor chip such as an IC or LSI, a liquid crystal panel, a CCD, a thin magnetic head, a micromachine, or the like). As shown in FIG. 8, in step 201 (design step), function/performance is designed for a device (e.g., circuit design for a semiconductor device) and a pattern to implement the function is designed. In step 202 (mask manufacturing step), a mask on which the designed circuit pattern is formed is manufactured. In step 203 (wafer manufacturing step), a wafer is manufacturing by using a silicon material or the like.

In step 204 (wafer processing step), an actual circuit and the like are formed on the wafer by lithography or the like using the mask and wafer prepared in steps 201 to 203, as will be described later. In step 205 (device assembly step), a device is assembled by using the wafer processed in step 204. Step 205 includes processes such as dicing, bonding, and packaging. (chip encapsulation).

Finally, in step 206 (inspection step), a test on the operation of the device, durability test, and the like are performed. After these steps, the device is completed and shipped out.

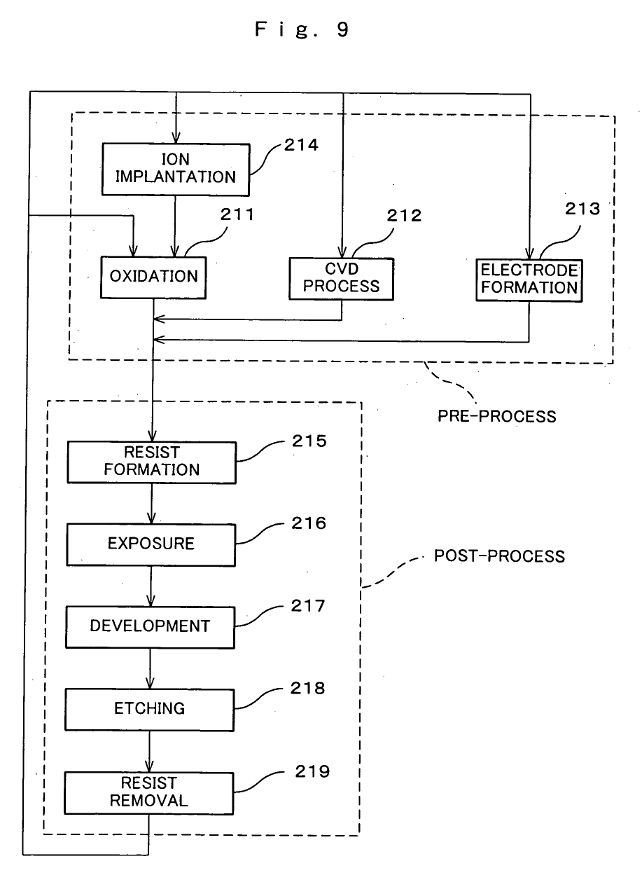

FIG. 9 is a flow chart showing a detailed example of step 204 described above in manufacturing the semiconductor device. Referring to FIG. 9, in step 211 (oxidation step), the surface of the wafer is oxidized. In step 212 (CVD step), an insulating film is formed on the wafer surface. In step 213 (electrode formation step), an electrode is formed on the wafer by vapor deposition. In step 214 (ion implantation step), ions are implanted into the wafer. Steps 211 to 214 described above constitute a pre-process for the respective steps in the wafer process and are selectively executed in accordance with the processing required in the respective steps.

When the above pre-process is completed in the respective steps in the wafer process, a post-process is executed as follows. In this post-process, first, in step 215 (resist formation step), the wafer is coated with a photosensitive agent. Next, as in step 216, the circuit pattern on the mask is transcribed onto the wafer by the above exposure apparatus and method. Then, in step 217 (developing step), the exposed wafer is developed. In step 218 (etching step), an exposed member on a portion other than a portion where the resist is left is removed by etching. Finally, in step 219 (resist removing step), the unnecessary resist after the etching is removed.

By repeatedly performing these pre-process and post-process, multiple circuit patterns are formed on the wafer.

A fine pattern with a minimum line width of about 0.1 μm can be formed on a wafer (substrate) with high precision by using the device manufacturing method of this embodiment described above, because the exposure apparatus and method of the above embodiment are used in the exposure step (step 216). This makes it possible to manufacture high-integration microdevices with high productivity (high yield).

While the above-described embodiments of the present invention are the presently preferred embodiments thereof, those skilled in the art of lithography systems will readily recognize that numerous additions, modifications and substitutions may be made to the above-described embodiments without departing from the spirit and scope thereof. It is intended that all such modifications, additions and substitutions fall within the scope of the present invention which is best defined by the claims appended below.

What is claimed is:

1. A transfer method of transporting an object to be transferred to/from a stage, comprising:
supporting one surface of said object on a plurality of support members;
loading said object supported by said plurality of support member onto said stage; and
withdrawing said plurality of support members from said object to an other surface side of said object after loading said object onto said stage.

2. The method according to claim 1, wherein said supporting comprises:
moving relatively said object and said plurality of support members such that contact portions of said plurality of support members are located on said one surface side of said object, the contact portions coming into contact with said object; and
moving said plurality of support members in respective predetermined directions within a moving plane perpendicular to a direction in which said object and said support member relatively are moved.

3. The method according to claim 2, wherein said supporting further comprises:
supporting said object on the contact portions of said support members by relatively moving said object and said plurality of support members, after respectively moving said plurality of support members in the respective predetermined directions.

4. The method according to claim 2, wherein the movements of said plurality of support members in the respective predetermined directions are rotational movements around a predetermined axis perpendicular to said moving plane.

5. The method according to claim 2, wherein movements of said plurality of support members in the respective predetermined directions are simultaneously performed.

6. The method according to claim 2, wherein movements of said plurality of support members in the respective predetermined directions are sequentially performed.

7. The method according to claim 2, wherein movements of said plurality of support members in the respective predetermined directions are linear movements.

8. The method according to claim 7, wherein the linear movements of said plurality of support members are linear movements in directions approaching/withdrawing from said object.

9. The method according to claim 7, wherein the linear movements of said plurality of support members are linear movements in directions parallel to radial directions to approach the center of said object.

10. The method according to claim 1, wherein said loading comprises:
relatively moving said plurality of support members and said stage so as to contact said one surface of said object with said stage; and
moving said plurality of support members thereafter in predetermined directions within a plane perpendicular to a direction in which said support members and said stage relatively are moved.

11. The method according to claim 1, further comprising:
moving relatively said stage and said plurality of support members such that contact portions of said support members are located on said one surface side of said object supported on said stage, the contact portion coming into contact with said object;
moving said plurality of support members in respective predetermined directions within a plane perpendicular to a direction in which said stage and said plurality of support members relatively are moved; and
unloading said object from said stage by relatively moving said plurality of support members and said stage.

12. The method according to claim 1, further comprising:
transferring said object to a position before said supporting, said one surface of said object can be supported at the position by said plurality of support members.

13. The method according to claim 1, further comprising:
positioning said object to said stage in a two-dimensional plane parallel to a surface of said object by relatively moving said plurality of support members and said stage along the two-dimensional plane before loading said object onto said stage.

14. The method according to claim 1, wherein openings are formed in said object, said plurality of support members can pass through said openings.

15. The method according to claim 14, wherein said object includes a mask and a frame member, a predetermined circuit pattern being formed on said mask, said frame member being securely fixed on said mask, and said openings being formed in said frame member.

16. An exposure method comprising:
supporting one surface of a first object by a plurality of support members;
loading said first object supported by said plurality of support members onto a stage;
withdrawing said plurality of support members from said first object to an other surface side of said object after said first object is loaded onto said stage; and
transcribing a pattern of said first object onto a second object through an optical system while detecting positions of said first object supported on said stage and said second object in an optical axis direction of said optical system.

17. The method according to claim 16, wherein the pattern of said first object is transcribed while said stage holding said first object and said second object are synchronously moved in predetermined directions within planes perpendicular to said optical axis of said optical system.

18. A transfer apparatus for transporting an object to be transferred to/from a stage, comprising:
a plurality of support members which supports one surface of said object; and
a first driving mechanism which drives said plurality of support members in a first direction between a first position on one surface side of said object and a second position on an other surface side opposite to said one surface side.

19. The apparatus according to claim 18, further comprising:
a second driving mechanism which drives said plurality of support members in respective directions within a plane perpendicular to said first direction.

20. The apparatus according to claim 19, wherein openings are formed in said object, said plurality of support members being able to be inserted/withdrawn through said openings in said first direction.

21. The apparatus according to claim 20, wherein said plurality of support members are able to move by a predetermined amount within said openings while said support members are inserted.

22. The apparatus according to claim 21, wherein said plurality of support members are able to rotate by a predetermined amount within said openings while said support members are inserted.

23. The apparatus according to claim 22, wherein said openings are arcuated through-holes.

24. The apparatus according to claim 22, wherein said openings are notches formed in an outer circumferential portion of said object.

25. The apparatus according to claim 20, wherein said object includes a mask and a frame member, a predetermined circuit pattern being formed on said mask, said frame member being securely fixed on said mask, and said openings are formed in said frame member.

26. The apparatus according to claim 25, wherein said mask is a circular mask, and said frame member is a support ring, said mask is mounted on said support ring.

27. The apparatus according to claim 18, further comprising:
an elastic member arranged on a contact portion of said support member, said contact portion coming into contact with said object.

28. The apparatus according to claim 18, further comprising:
a cylindrical cover arranged around a driving shaft of said first driving mechanism.

29. An exposure apparatus for transcribing a pattern formed on a first object onto a second object through an optical system, comprising:
a stage which mounts said first object; and
a transfer system which transports said first object to/from said stage, said transfer system including
a plurality of support members which supports one surface of said first object; and
a first driving mechanism which drives said plurality of support members in a first direction between a first position on said one surface side of said object and a second position on said other surface side opposite to said one surface.

30. The apparatus according to claim 29, wherein said stage moves between a transportation position and an exposure position, said first object being transported to/from said transfer system at said transportation position, and the pattern being transcribed onto said second object at said exposure position.

31. The apparatus according to claim 30, further comprising:
an interferometer system which manages the transport and exposure positions and a position of said stage during movement between the transport and exposure positions.

32. The apparatus according to claim 31, wherein said interferometer system comprises:
a first interferometer subsystem which manages the position of said stage, located at the transportation position, in a two-dimensional plane perpendicular to the first direction; and
a second interferometer subsystem which manages the position of said stage, located at the exposure position, in the two-dimensional plane, and wherein
interferometer beams from said first and second interferometer subsystems simultaneously irradiate a single reflecting surface of said stage while said stage is moving between the transportation position and the exposure position.

33. The apparatus according to claim 29, further comprising:
a measurement device, said measuring device including
a mark detection system arranged on a side of said optical system at the transportation position, and wherein
said measurement device system detects a positioning mark formed on said first object before said first object is loaded onto said stage.

34. The apparatus according to claim 29, wherein said optical system is an electron optical system.

35. The apparatus according to claim 29, wherein a mounting surface to mount said first object is formed on a bottom surface of a recess portion formed in said stage.

36. A method of manufacturing an exposure apparatus' for transcribing a pattern formed on a first object onto a second object through an optical system, comprising:
providing a first stage which mounts said first object;
providing a transfer apparatus which transports said first object to/from said first stage, said transfer apparatus including:
a plurality of support members which supports one surface of said first object; and
a first driving mechanism which drives said plurality of support members in a first direction between a first position on one surface side of said object and a second position on said other surface side opposite to said one surface;
providing said optical system; and
providing a second stage which mounts said second object.

37. The method according to claim 36, further comprising:
providing an interferometer system which manages a transport position, an exposure position, and a position of said first stage during movement between the transport and exposure positions, said first object being transported to/from said transfer apparatus at said transportation position, said pattern being transcribed onto said second object at said exposure position, and said first stage moving between said transportation position and said exposure position.

38. A device manufacturing method comprising: performing a lithographic process by using said exposure apparatus defined in claim 29.
